(19) United States
(12) Patent Application Publication
(10) Pub. No.: US 2012/0119184 A1
(43) Pub. Date: May 17, 2012

(54) Vertical Light Emitting Diode (VLED) Die Having N-Type Confinement Structure With Etch Stop Layer And Method Of Fabrication

(76) Inventors: Kung-Hsieh Hsu, (US); Yao-Kuo Wang, (US); Wen-Huang Liu, (US); Chuong Anh Tran, (US)

(21) Appl. No.: 12/944,823

(22) Filed: Nov. 12, 2010

(51) Int. Cl. H01L 33/04; H01L 21/31

(52) U.S. Cl. 257/13; 438/38; 257/E33.008; 257/E21.24

(57) ABSTRACT

A vertical light emitting diode (VLED) die includes a p-type confinement layer, an active layer on the p-type confinement layer configured to emit light, and an n-type confinement structure having at least one etch stop layer configured to protect the active layer. A method for fabricating a vertical light emitting diode (VLED) die includes the steps of: providing a carrier substrate; forming an n-type confinement structure on the carrier substrate having at least one etch stop layer; forming an active layer on the n-type confinement structure; forming a p-type confinement layer on the active layer; and removing the carrier substrate.

### BACKGROUND

This disclosure relates generally to optoelectronic components and more particularly to vertical light emitting diode (VLED) dice, and to methods for fabricating the vertical light emitting diode (VLED) dice.

One type of light emitting diode (LED) die, known as a vertical light emitting diode (VLED) die, includes an epitaxial structure made of a compound semiconductor material, such as GaN, AlN or InN formed on a carrier substrate. Following the fabrication process, the epitaxial structure is separated from the carrier substrate. The epitaxial structure can include a p-type confinement layer, an n-type confinement layer, and an active layer (multiple quantum well (MQW) layer) between the confinement layers configured to emit light. In the epitaxial structure, the n-type confinement layer can comprise multiple n-type layers, and can also include one or more buffer layers, such as a SiN layer for decreasing dislocation density.

One method for increasing the light extraction from a vertical light emitting diode (VLED) die is to roughen and texture the surface of the n-type confinement layer using a process such as photo-electrical chemical oxidation and etching. For example, processes for roughening the n-type confinement layer are disclosed in U.S. Pat. Nos. 7,186,580 B2; 7,473,936 B2; 7,524,686 B2; 7,563,625 B2 and 7,629,195 B2 assigned to SemiLEDs Corporation located in Boise, Id. and Miao-Li County, Taiwan, R.O.C.

An epitaxial structure for a prior art light emitting diode (LED) die is illustrated in FIG. 11A. The epitaxial structure includes a p-type confinement layer 112, an active layer (multiple quantum well (MQW) layer) 114 configured to emit light, and an n-type confinement layer 116 having a textured surface 118 formed using an etching process. One problem that can occur during the etching process is that the active layer 114, particularly the p-n junctions, can be damaged by the chemical solutions used during the etching process. For example, in FIG. 11A the active layer 114 includes areas 120 that have been damaged by etching. These damaged areas 120 form a path for leakage current in the reverse bias state of the vertical light emitting diode (VLED) die. As shown in FIG. 11B, the leakage current in the reverse bias state can be observed using infrared emission microscopy (EMMI) as a bright spot. In addition to bright spots, the damaged areas 120 can also produce a low forward voltage at low bias currents, as the damage provides a path for current that bypasses the pn junction barrier.

The present disclosure is directed to a vertical light emitting diode (VLED) die having an n-type confinement structure with an etch stop layer for protecting the active layer. The present disclosure is also directed to a method for fabricating a vertical light emitting diode (VLED) die with an n-type confinement structure having an etch stop layer.

### SUMMARY

A vertical light emitting diode (VLED) die comprises an epitaxial structure that includes a p-type confinement layer comprising at least one p-type semiconductor layer, an active layer on the p-type confinement layer configured as a multiple quantum well (MQW) configured to emit light, and an n-type confinement structure comprising at least one n-type semiconductor layer and at least one etch stop layer comprising a semiconductor material configured to protect the active layer. The n-type confinement structure can include multiple n-type semiconductor layers, such as an inner layer proximate to the active layer and an outer layer having a textured surface, and the etch stop layer can be located between these layers. As another alternative, the n-type confinement structure can include one or more etch stop layers combined with one or more buffer layers separated by multiple n-type semiconductor layers.

A method for fabricating a vertical light emitting diode (VLED) die includes the steps of: providing a carrier substrate; forming an n-type confinement structure on the carrier substrate comprising at least one n-type semiconductor layer and at least one etch stop layer comprising a semiconductor material; forming an active layer on the n-type confinement structure; forming a p-type confinement layer comprising at least one p-type semiconductor layer on the active layer; and removing the carrier substrate. The method can also include the step of texturing an outer surface of the n-type confinement structure using an etching process confined by the etch stop layer.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIG. 1 is a schematic cross sectional view of a vertical light emitting diode (VLED) die having an n-type confinement structure with an etch stop layer and a buffer layer;

FIG. 2 is a schematic cross sectional view of a vertical light emitting diode (VLED) die having an n-type confinement structure with multiple etch stop layers and multiple buffer layers;

FIG. 2A is an enlarged exploded portion of FIG. 2 showing the etch stop layers and the buffer layers;

FIG. 3 is a schematic cross sectional view of a vertical light emitting diode (VLED) die having an n-type confinement structure with a single etch stop layer;

FIG. 4 is a schematic cross sectional view of a vertical light emitting diode (VLED) die having an n-type confinement structure with multiple etch stop layers;

FIG. 4A is an enlarged exploded portion of FIG. 4 showing the etch stop layers and the buffer layers;

FIG. 5 is a schematic cross sectional view of a vertical light emitting diode (VLED) die having an n-type confinement structure with multiple etch stop layers and multiple buffer layers;

FIG. 5A is an enlarged exploded portion of FIG. 2 showing the etch stop layers and the buffer layers;

FIG. 6 is a schematic cross sectional view of a vertical light emitting diode (VLED) die having an n-type confinement structure with a single etch stop layer and multiple buffer layers;

FIG. 6A is an enlarged exploded portion of FIG. 6 showing the etch stop layer and the buffer layers;

FIG. 7A is a schematic cross sectional view of a vertical light emitting diode (VLED) package constructed with the vertical light emitting diode (VLED) die;

FIG. 7B is an emission microscopy (EMMI) graph showing emission characteristics of the vertical light emitting diode (VLED) package of FIG. 7A;

FIGS. 8A-8D are schematic cross sectional views illustrating steps in a method for fabricating the vertical light emitting diode (VLED) die;

FIG. 9A is an enlarged schematic cross sectional view of the epitaxial structure of the vertical light emitting diode (VLED) die following a roughening process on the surface of the n-type confinement structure;

FIG. 9B is a SEM graph of the textured surface of the n-type confinement structure of the vertical light emitting diode (VLED) die;

FIG. 10A is a graph illustrating leakage current at a reverse voltage of −5V for the vertical light emitting diode (VLED) die versus a prior art (standard) die;

FIG. 10B is a graph illustrating forward voltage at a low forward current of 10 μA for the vertical light emitting diode (VLED) die versus a prior art (standard) die;

FIG. 10C is a graph illustrating forward voltage at a low forward current of 1 μA for the vertical light emitting diode (VLED) die versus a prior art (standard) die;

FIG. 11A is an enlarged schematic cross sectional view of a prior art vertical light emitting diode (VLED) die having an epitaxial structure with an n-type confinement structure having a textured surface; and

FIG. 11B is an emission microscopy (EMMI) graph of the prior art vertical light emitting diode (VLED) die illustrating a bright spot from leakage current in the reverse bias state.

### DETAILED DESCRIPTION

In the figures similar reference numerals refer to similar layers or parts. The suffixes A-F in the reference numerals refer to different embodiments, and the suffixes 1-3 in the reference numerals refer to the number of layers.

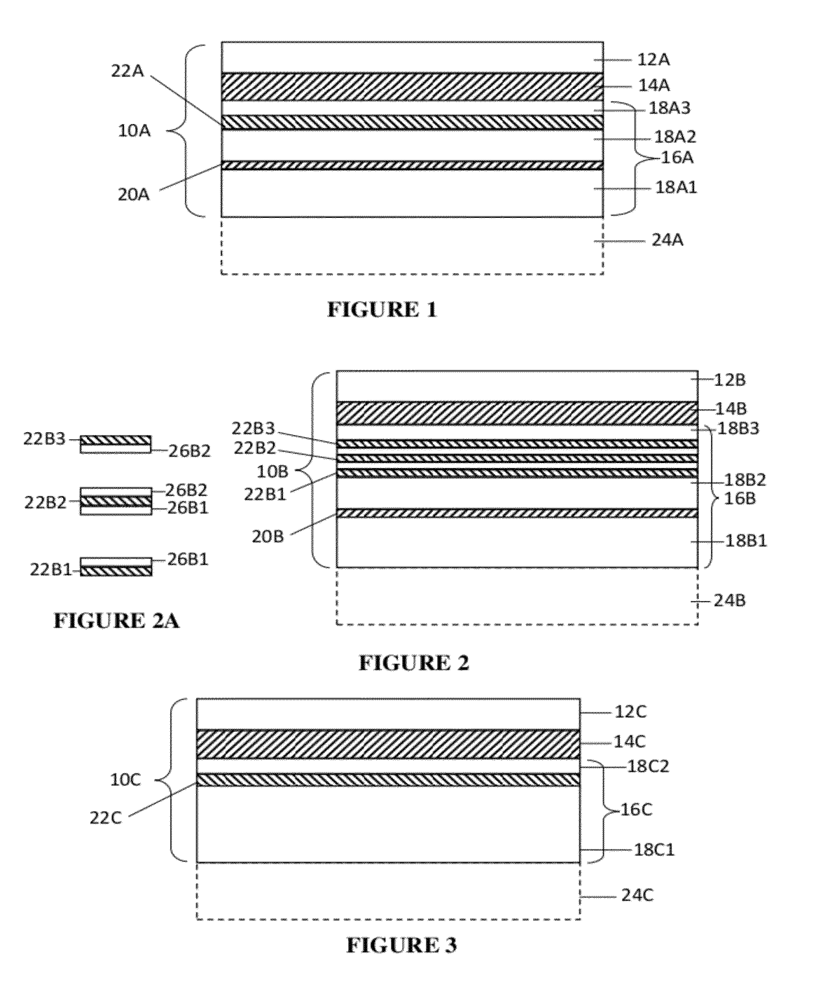

Referring to FIG. 1, a vertical light emitting diode (VLED) die 10A comprises an epitaxial structure that includes a p-type confinement layer 12A, an active layer 14A on the p-type confinement layer 12A configured to emit light, and an n-type confinement structure 16A on the active layer 14A. As will be further explained, the vertical light emitting diode (VLED) die 10A is characterized by a low reverse bias leakage current and a high forward voltage at low bias currents.

The n-type confinement structure 16A includes an outer n-type layer 18A1, a buffer layer 20A, a center n-type layer 18A2, an etch stop layer 22A and an inner n-type layer 18A3. The vertical light emitting diode (VLED) die 10A is initially constructed on a carrier substrate 24A, which as indicated by dotted lines is subsequently removed. Suitable materials for the carrier substrate 24A include sapphire, silicon carbide (SiC), silicon (Si), germanium (Ge), zinc oxide (ZnO), gallium nitride (GaN), aluminum nitride (AlN), zinc selenium (ZnSe) and gallium arsenide (GaAs).

The p-type confinement layer 12A (FIG. 1) preferably comprises p-GaN. Other suitable materials for the p-type confinement layer 12A include p-AlGaN, p-InGaN, p-AlInGaN, p-AlInN and p-AlN. The active layer 14A (FIG. 1) preferably includes one or more quantum wells comprising one or more layers of InGaN/GaN, AlGaInN, AlGaN, AlInN and AlN. The n-type layers (18A1, 18A2, 18A3) preferably comprises n-GaN. Other suitable materials for the n-type layers (18A1, 18A2, 18A3) include n-AlGaN, n-InGaN, n-AlInGaN, AlInN and n-AlN. The buffer layer 20A is configured to perform a specific function in the vertical light emitting diode (VLED) die 10A. For example, the buffer layer 20A can comprise gallium nitride (GaN). As another example, the buffer layer 20A can comprise silicon nitride (SiN) configured to reduce the density of dislocations and compositional fluctuations in the active layer 14A.

The etch stop layer 22A (FIG. 1) comprises a material that is less reactive to an etching process than the material of the n-type layers (18A1, 18A2, 18A3). Stated differently, the etch rate of the etch stop layer 22A is less than the etch rate of the n-type layers (18A1, 18A2, 18A3). In addition, the etch stop layer 22A includes Al, but can also include additional elements. For example, with the n-type layers (18A1, 18A2, 18A3) comprising n-GaN, the etch stop layer 22A can comprise doped or undoped GaN with Al, or another element, such as In, Si, C, Ge, Se, Te or P in the form of composition or dopant. By way of example, with the etch stop layer 22A comprising AlInGaN, a representative Al content can be from 1% to 100% (e.g., AlN for 100%). Other suitable materials for the etch stop layer 22A include AlGaN and AlInN, in either doped or undoped form. In the case of AlGaN, the etch stop layer 22A can also include In, Mg, Si, P, C, Se or Te, in the form of composition or dopant. In the case of AlN, the etch stop layer 22A can also include Ga, In, Mg, Si, P, C, Se or Te, in the form of composition or dopant. A representative thickness of the etch stop layer 22A can be from 1 Å to 1 μm.

Each of the vertical light emitting diodes (VLED) dice 10B-10F to be hereinafter described can be formed of the same materials as described for the vertical light emitting diode (VLED) die 10A. In addition, each of the vertical light emitting diode (VLED) dice 10B-10F to be hereinafter described is characterized by a low reverse bias leakage current and a high forward voltage at low bias currents.

Referring to FIGS. 2 and 2A, a vertical light emitting diode (VLED) die 10B comprises an epitaxial structure that includes a p-type confinement layer 12B, an active layer 14B on the p-type confinement layer 12B configured to emit light, and an n-type confinement structure 16B on the active layer 14B. The n-type confinement structure 16B includes an outer n-type layer 18B1, a buffer layer 20B, a center n-type layer 18B2, a plurality of etch stop layers 22B1, 22B2, 22B3 and an inner n-type layer 18B3. As shown in FIG. 2A, the etch stop layers 22B1, 22B2, 22B3 are separated by n-type separation layers 26B1, 26B2. The vertical light emitting diode (VLED) die 10B is initially constructed on a carrier substrate 24B, which as indicated by dotted lines is subsequently removed.

Referring to FIG. 3, a vertical light emitting diode (VLED) die 10C comprises an epitaxial structure that includes a p-type confinement layer 12C, an active layer 14C on the p-type confinement layer 12C configured to emit light, and an n-type confinement structure 16C on the active layer 14C. The n-type confinement structure 16C includes an outer n-type layer 18C1, an etch stop layer 22C and an inner n-type layer 18C2. The vertical light emitting diode (VLED) die 10C is initially constructed on a carrier substrate 24C, which as indicated by dotted lines is subsequently removed.

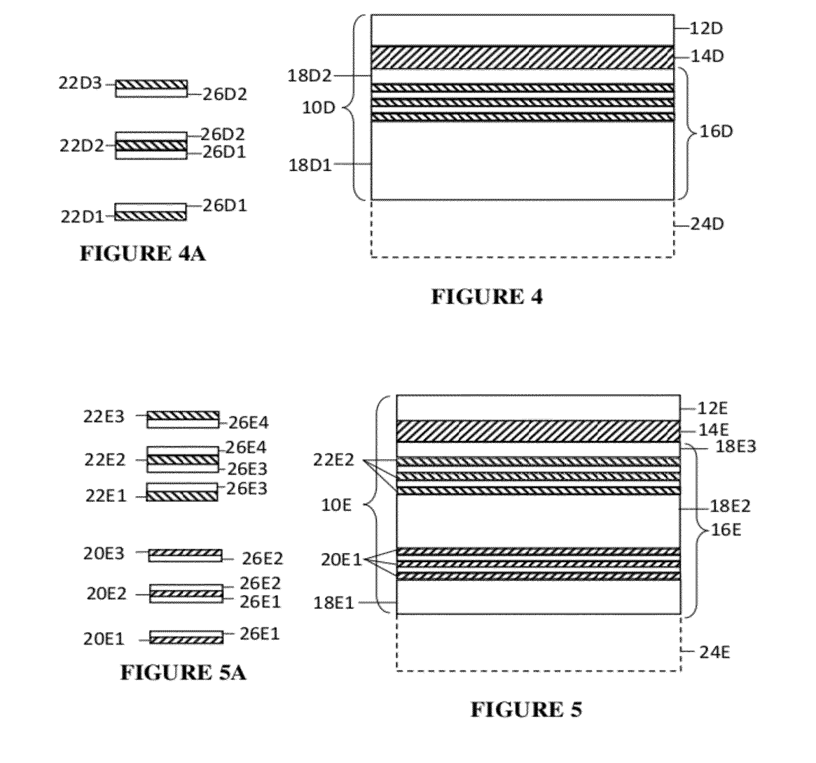

Referring to FIGS. 4 and 4A, a vertical light emitting diode (VLED) die 10D comprises an epitaxial structure that includes a p-type confinement layer 12D, an active layer 14D on the p-type confinement layer 12D configured to emit light, and an n-type confinement structure 16D on the active layer 14D. The n-type confinement structure 16D includes an outer n-type layer 18D1, a plurality of etch stop layers 22D1, 22D2, 22D3 and an inner n-type layer 18D2. As shown in FIG. 4A, the etch stop layers 22D1, 22D2, 22D3 are separated by n-type separation layers 26D1, 26D2. The vertical light emitting diode (VLED) die 10D is initially constructed on a carrier substrate 24D, which as indicated by dotted lines is subsequently removed.

Referring to FIGS. 5 and 5A, a vertical light emitting diode (VLED) die 10E comprises an epitaxial structure that includes a p-type confinement layer 12E, an active layer 14E on the p-type confinement layer 12E configured to emit light, and an n-type confinement structure 16E on the active layer 14E. The n-type confinement structure 16E includes an outer n-type layer 18E1, a plurality of outer buffer layers 20E1, 20E2, 20E3 separated by n-type separation layers 26E1, 26E2, a center n-type layer 18E2, a plurality of inner etch stop layers 22E1, 22E2, 22E3 separated by n-type separation layers 26E3, 26E4, and an inner n-type layer 18E3. The vertical light emitting diode (VLED) die 10E is initially constructed on a carrier substrate 24E, which as indicated by dotted lines is subsequently removed.

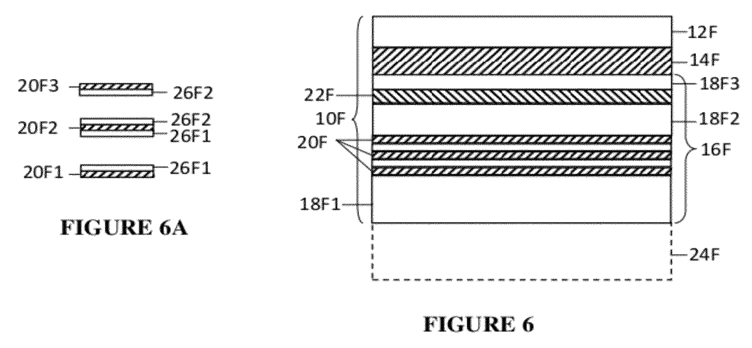

Referring to FIGS. 6 and 6A, a vertical light emitting diode (VLED) die 10F comprises an epitaxial structure that includes a p-type confinement layer 12F, an active layer 14F on the p-type confinement layer 12F configured to emit light, and an n-type confinement structure 16F on the active layer 14F. The n-type confinement structure 16F includes an outer n-type layer 18F1, a plurality of buffer layers 20F1, 20F2 separated by n-type separation layers 26F1, 26F2, a center n-type layer 18F2, an etch stop layer 22F, and an inner n-type layer 18F3. The vertical light emitting diode (VLED) die 10F is initially constructed on a carrier substrate 24F, which as indicated by dotted lines is subsequently removed.

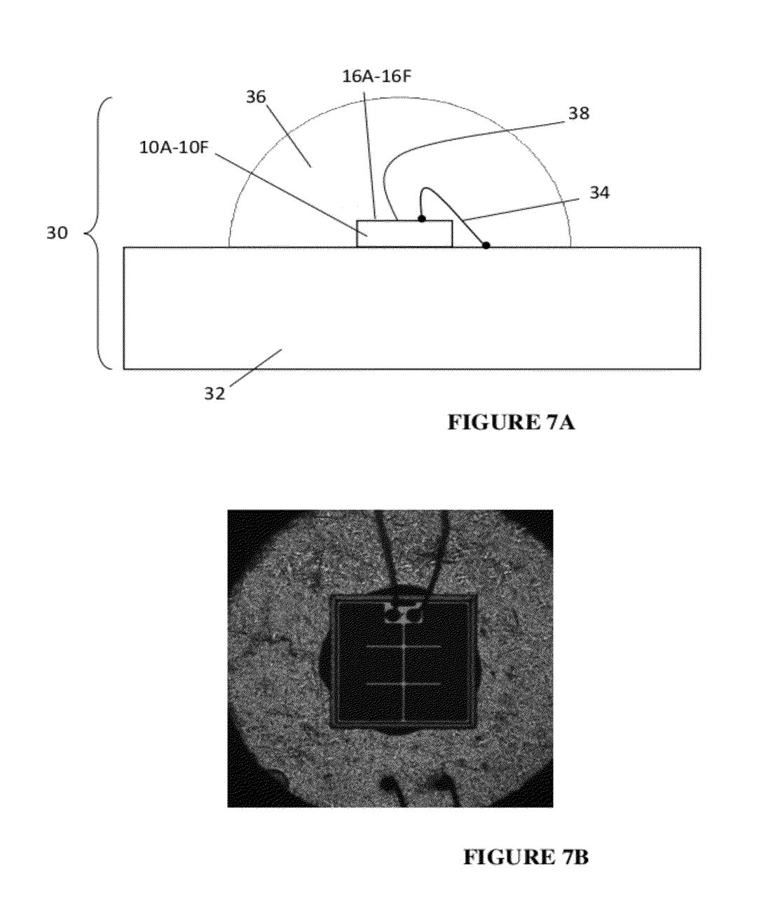

Referring to FIG. 7A, a vertical light emitting diode (VLED) package 30 constructed using the any of the previously described vertical light emitting diode (VLED) dice 10A-10F is illustrated. The vertical light emitting diode (VLED) package 30 includes a substrate 32; at least one vertical light emitting diode (VLED) die 10A-10F mounted to the substrate 32; a wire 34 bonded to the vertical light emitting diode (VLED) die 10A-10F and to the substrate 32; and a transparent dome 36 configured as a lens encapsulating the vertical light emitting diode (VLED) die 10A-10F. In addition, the surface 38 of the n-type confinement structure 16A-16F of the vertical light emitting diode (VLED) die 10A-10F can be textured to improve light extraction. The etch stop layers 22A-22F allow the active layers 14A-14F to be protected during fabrication, such that the vertical light emitting diode (VLED) die 10A-10F has a low leakage current in the reverse bias direction, and a higher forward voltage at low bias currents. Further, as illustrated in the emission microscopy (EMMI) graph of FIG. 7B, bright spots resulting from leakage current are substantially eliminated.

The substrate 32 (FIG. 7A) of the vertical light emitting diode (VLED) package 30 (FIG. 7A) functions as a mounting substrate, and also provides electrical conductors (not shown), electrodes (not shown) and electrical circuits (not shown) for electrically connecting the light emitting diode (LED) package 30 to the outside world. The substrate 32 (FIG. 7A) can have a flat shape as shown or can have a convex shape or a concave shape. In addition, the substrate 32 (FIG. 7A) can include a reflective layer (not shown) to improve light extraction. The substrate 32 (FIG. 7A) can comprise silicon, or another semiconductor material such as GaAs, SiC, GaP, GaN or AlN. Alternately, the substrate 32 (FIG. 7A) can comprise a ceramic material, sapphire, glass, a printed circuit board (PCB) material, a metal core printed circuit board (MCPCB), an FR-4 printed circuit board (PCB), a metal matrix composite, a metal lead frame, an organic lead frame, a silicon submount substrate, or any packaging substrate used in the art. Further, the substrate 32 (FIG. 7A) can comprise a single layer of metal or metal alloyed layers, or multiple layers such as Si, AlN, SiC, AlSiC, diamond, MMC, graphite, Al, Cu, Ni, Fe, Mo, CuW, CuMo, copper oxide, sapphire, glass, ceramic, metal or metal alloy. In any case, the substrate 32 (FIG. 7A) preferably has an operating temperature range of from about 60° C. to 350° C.

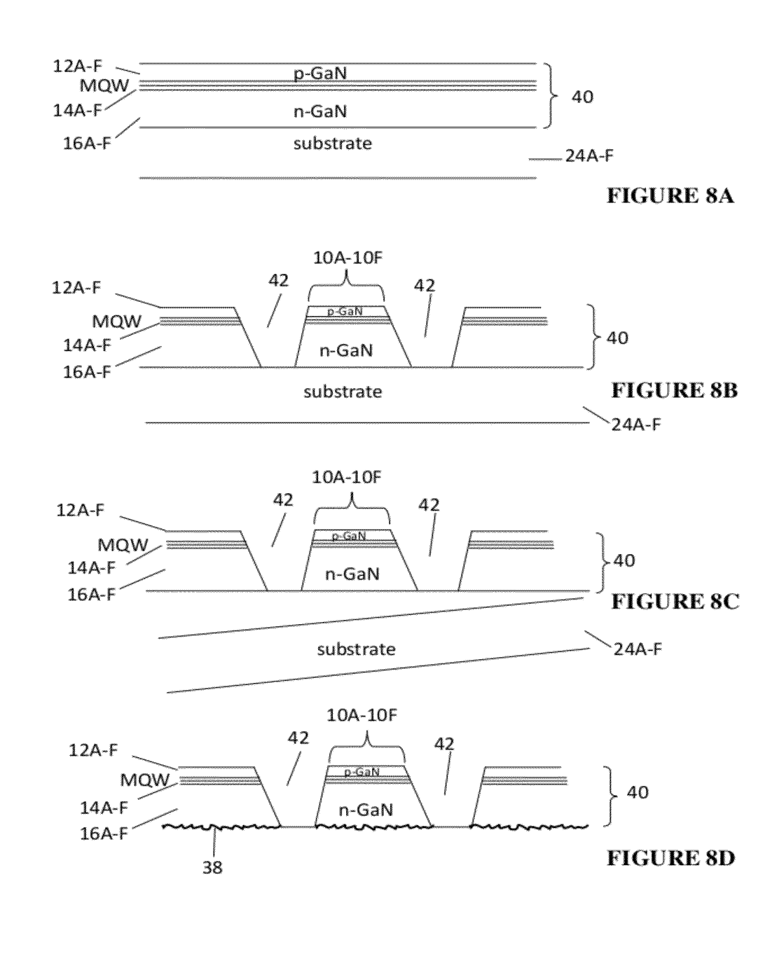

Referring to FIGS. 8A-8D, steps in a method for fabricating the previously described vertical light emitting diode (VLED) dice 10A-F are illustrated. Initially, as shown in FIG. 8A, the carrier substrate 24A-F is provided. The carrier substrate 24A-F can be in the form of a wafer comprised of a suitable material, such as sapphire, silicon carbide (SiC), silicon (Si), germanium (Ge), zinc oxide (ZnO), gallium nitride (GaN), aluminum nitride (AlN), zinc selenium (ZnSe) and gallium arsenide (GaAs). In the examples to follow the carrier substrate 24A-F comprises sapphire.

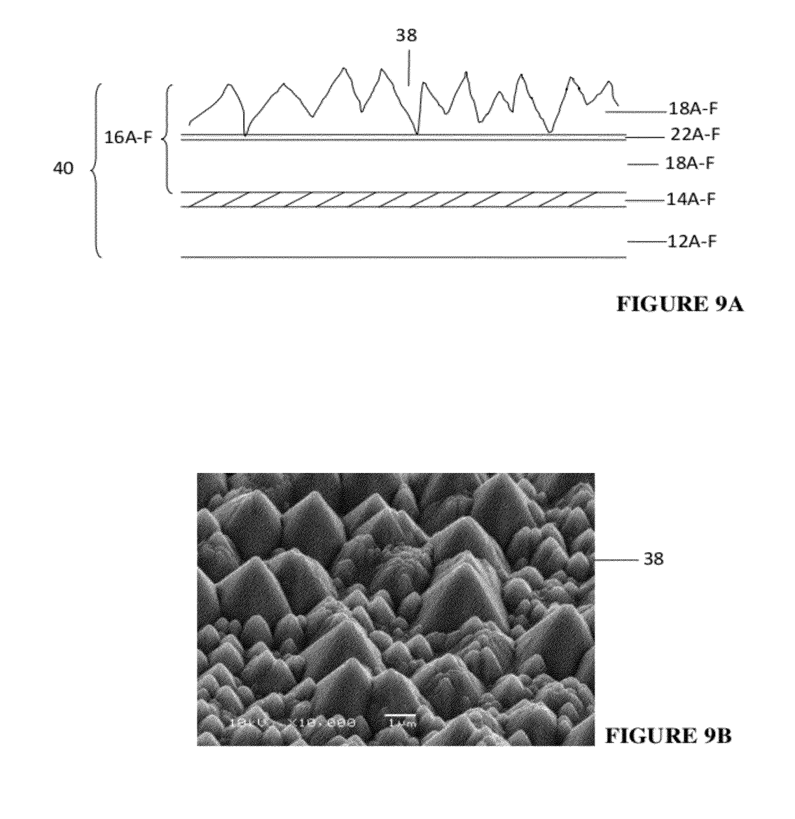

As also shown in FIG. 8A, a multi layer epitaxial structure 40 is formed on the carrier substrate 24A-F. The epitaxial structure 40 includes the p-type confinement layer 12A-F, the active layer 14A-F on the p-type confinement layer 12A-F configured to emit light (designated MQW in FIGS. 8A-D), and an n-type confinement structure 16A-F on the active layer 14A-F. As also shown in FIG. 9A, all of these layers including the separate layers of the n-type confinement structure 16A-F such as the etch stop layers 22A-F, the buffer layers 20A-F and the n-type layers 18A-F can be fabricated using a suitable deposition process such as vapor phase epitaxy (VPE), metal organic chemical vapor deposition (MOCVD), molecular beam epitaxy (MBE) or liquid phase epitaxy (LPE). In the illustrative embodiment, the p-type confinement layer 12A-F comprises p-GaN and the n-type layers 18A-18F comprises n-GaN. Rather than GaN, the p-type confinement layer 12A-F and the n-type layers 18A-18F can comprise various other compound semiconductor materials, such as AlGaN, InGaN, and AlInGaN. The active layer 14A-14F can be formed of suitable materials such as an InGaN layer sandwiched between two layers of a material with a wider bandgap such as GaN.

Next as shown in FIG. 8B, a suitable process can be used to form trenches 42 through the epitaxial structure 40 that can endpoint on the substrate 24A-F as shown, or alternately that can extend a short distance into the substrate 24A-F. In addition, prior to forming the trenches other elements such as reflector layers (not shown) and bases (not shown) can be formed as required. The trenches 42 can be formed in a criss-cross pattern similar to the streets between dice in a conventional semiconductor fabrication process, such that a plurality of defined dice 10A-10F are formed. A suitable process for forming the trenches 42 comprises dry etching through a hard mask. Other suitable processes include laser cutting, saw cutting, diamond cutting, wet etching, dry etching and water jetting.

Next as shown in FIG. 8C, the carrier substrate 24A-F can be removed from the n-type confinement structures 16A-F using a suitable process such as a pulse laser irradiation process, etching, or chemical mechanical planarization (CMP).

Next as shown in FIG. 8D, the textured surface 38 can be formed on the outer surface of the n-type confinement structures 16A-F using a roughening (or texturing) process. One process for roughening the outer surfaces of the n-type confinement structures 16A-F combines photo-electrochemical oxidation and etching. This process is described in U.S. Pat. Nos. 7,186,580 B2; 7,473,936 B2; 7,524,686 B2; 7,563,625 B2 and 7,629,195 B2, which are incorporated herein by reference. The textured surface 38 is illustrated schematically in FIG. 9A, and in a SEM graph in FIG. 9B. During the etching process, the etch stop layers 22A-F provide an etch stop to protect the active layer 14A-F.

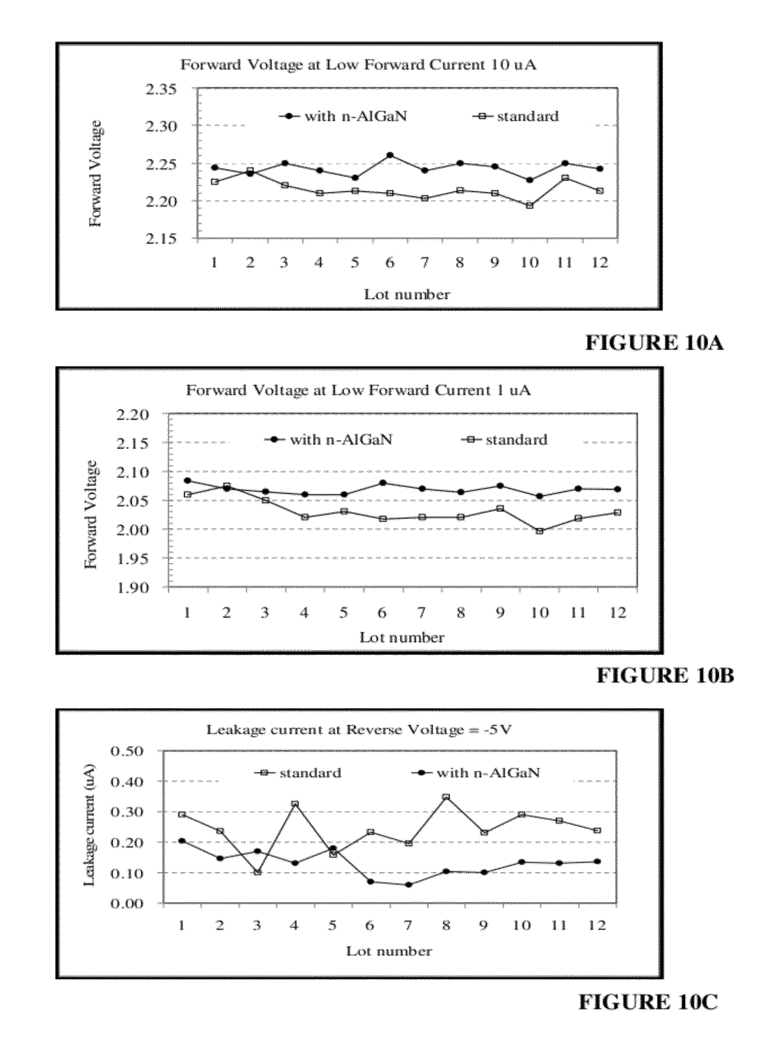

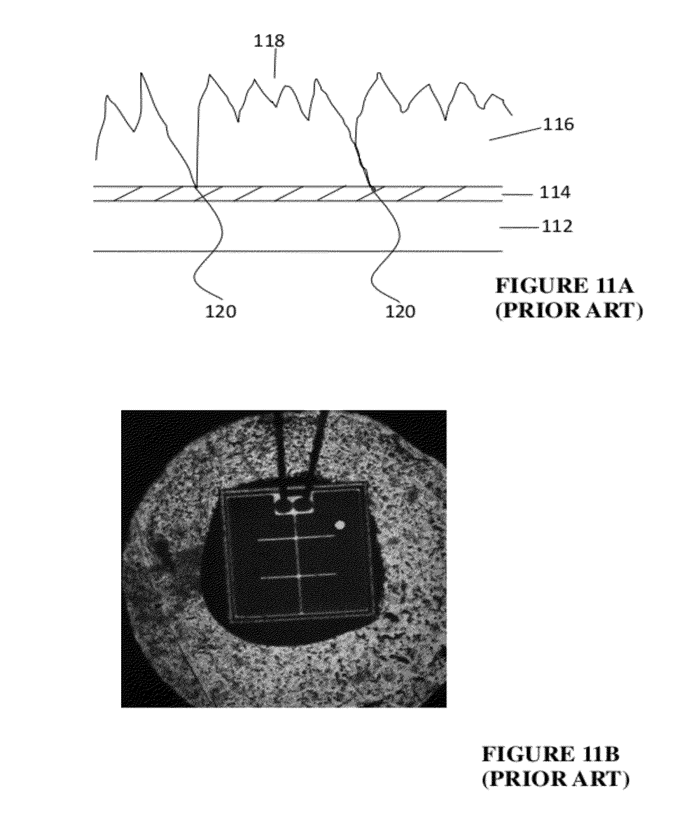

Referring to FIGS. 10A and 10B, electrical characteristics of the vertical light emitting diode (VLED) dice 10A-10F are illustrated. As illustrated in FIG. 10A, leakage current at a reverse voltage of −5 volts is less for dice having an etch stop layer formed of n-AlGaN (lower plotted line) than for standard (prior art) vertical light emitting diode (VLED) dice (upper plotted line). As illustrated in FIG. 10B, forward voltage at a low forward current of 10 μA is larger for dice having an etch stop layer formed of n-AlGaN (lower plotted line) than for standard (prior art) vertical light emitting diode (VLED) dice (upper plotted line). As illustrated in FIG. 10C, forward voltage at a low forward current of 1 μA is larger for dice having an etch stop layer formed of n-AlGaN (lower plotted line) than for standard (prior art) vertical light emitting diode (VLED) dice (upper plotted line).

Thus the disclosure describes an improved vertical light emitting diode (VLED) die having an n-type confinement structure with at least one etch stop layer, and a method for fabricating the vertical light emitting diode (VLED) die. While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A vertical light emitting diode (VLED) die comprising:
a p-type confinement layer comprising at least one p-type semiconductor layer;
an active layer on the p-type confinement layer comprising a multiple quantum well (MQW) configured to emit light; and
an n-type confinement structure comprising at least one n-type semiconductor layer and at least one etch stop layer comprising a semiconductor material configured to protect the active layer.

2. The vertical light emitting diode (VLED) die of claim 1 wherein the n-type confinement layer comprises an inner n-type semiconductor layer on the active layer, the etch stop layer on the n-type semiconductor layer, and an outer n-type semiconductor layer on the etch stop layer having a textured surface.

3. The vertical light emitting diode (VLED) die of claim 1 wherein the semiconductor material includes Al.

4. The vertical light emitting diode (VLED) die of claim 1 wherein the p-type semiconductor material comprises p-GaN, the n-type semiconductor material comprises n-GaN and the semiconductor material comprises GaN and Al.

5. The vertical light emitting diode (VLED) die of claim 1 wherein the semiconductor material includes GaN and Al and an element selected from the group consisting of In, Si, C, Ge, Se, Te and P.

6. The vertical light emitting diode (VLED) die of claim 1 wherein the semiconductor material comprises a material selected from the group consisting of AlInGaN, AlGaN, AN and AlInN.

7. The vertical light emitting diode (VLED) die of claim 1 wherein the semiconductor material comprises a material selected from the group consisting of AlInGaN, AlGaN, AlN and AlInN and an element selected from the group consisting of In, Si, C, Ge, Se, Te and P.

8. The vertical light emitting diode (VLED) die of claim 1 wherein the n-type confinement structure comprises a plurality of etch stop layers separated by a plurality of n-type separation layers.

9. The vertical light emitting diode (VLED) die of claim 1 wherein the n-type confinement structure comprises at least one buffer layer.

10. The vertical light emitting diode (VLED) die of claim 9 wherein the p-type semiconductor material comprises p-GaN, the n-type semiconductor material comprises n-GaN, the semiconductor material comprises a material selected from the group consisting of AlInGaN, AlGaN, AlN and AlInN, and the buffer layer comprises GaN or SiN.

11. The vertical light emitting diode (VLED) die of claim 1 wherein the n-type confinement structure comprises a plurality of buffer layers and a plurality of etch stop layers separated by a plurality of n-type separation layers.

12. A vertical light emitting diode (VLED) die comprising:
a p-type confinement layer comprising at least one p-type semiconductor layer;
an active layer on the p-type confinement layer comprising a multiple quantum well (MQW) configured to emit light; and
an n-type confinement structure comprising an inner n-type semiconductor layer on the active layer, an etch stop layer on the n-type semiconductor layer comprising a semiconductor material having an etch rate less than that of the n-type semiconductor layer, a center n-type semiconductor layer on the etch stop layer, and an outer n-type semiconductor layer on the n-type semiconductor layer having a textured surface.

13. The vertical light emitting diode (VLED) die of claim 12 wherein the p-type semiconductor material comprises p-GaN, the n-type semiconductor material comprises n-GaN and the semiconductor material comprises a material selected from the group consisting of AlInGaN, AlGaN, AN and AlInN.

14. The vertical light emitting diode (VLED) die of claim 13 wherein the semiconductor material includes an element selected from the group consisting of Si, C, Ge, Se, Te and P in composition or doped form.

15. The vertical light emitting diode (VLED) die of claim 12 wherein the n-type confinement structure further comprises at least one buffer layer comprising GaN or SiN.

16. The vertical light emitting diode (VLED) die of claim 12 wherein the n-type confinement structure comprises a plurality of etch stop layers separated by a plurality of n-type separation layers.

17. The vertical light emitting diode (VLED) die of claim 12 wherein the n-type confinement structure comprises a plurality of buffer layers separated by a plurality of n-type separation layers.

18. The vertical light emitting diode (VLED) die of claim 12 wherein the n-type confinement structure comprises a plurality of etch stop layers and a plurality of buffer layers separated by a plurality of n-type separation layers.

19. A method for fabricating a vertical light emitting diode (VLED) die comprising:
providing a carrier substrate;
forming an n-type confinement structure on the carrier substrate comprising at least one n-type semiconductor layer and at least one etch stop layer comprising a semiconductor material;
forming an active layer on the n-type confinement structure comprising a multiple quantum well (MQW) configured to emit light;
forming a p-type confinement layer comprising at least one p-type semiconductor layer on the active layer; and
removing the carrier substrate.

20. The method of claim 19 further comprising texturing an outer surface of the n-type confinement structure using an etching process confined by the etch stop layer.

21. The method of claim 19 wherein the p-type semiconductor material comprises p-GaN, the n-type semiconductor material comprises n-GaN and the semiconductor material comprises a material selected from the group consisting of AlInGaN, AlGaN, AN and AlInN.

22. The method of claim 19 further comprising forming at least one SiN buffer layer on the n-type confinement structure.

23. The method of claim 19 further comprising forming a plurality of etch stop layers on the n-type confinement structure separated by a plurality of n-type separation layers.

24. The method of claim 19 further comprising forming a plurality of buffer layers on the n-type confinement structure separated by a plurality of n-type separation layers.

25. The method of claim 19 further comprising forming a plurality of etch stop layers and a plurality of buffer layers on the n-type confinement structure separated by a plurality of n-type separation layers.

26. The method of claim 19 wherein the carrier substrate comprises a material selected from the group consisting of sapphire, SiC, Si, Ge, ZnO, GaN, AN, ZnSe and GaAs.
